(19) United States
(12) Patent Application Publication
(10) Pub. No.: US 2014/0028415 A1
(43) Pub. Date: Jan. 30, 2014

(54) FREQUENCY-TUNABLE BAND-PASS FILTER FOR MICROWAVE

(71) Applicants: THALES, Neuilly-sur-Seine (FR); CENTRE NATIONAL D'ETUDES SPATIALES - CNES, Paris (FR); CENTRE NATIONAL DE LA RECHERCHE SCIENTIFIQUE - CNRS, Paris (FR)

(72) Inventors: Aurelien PERIGAUD, Panazol (FR); Damien PACAUD, Beaumont Sur Leze (FR); Nicolas DELHOTE, Limoges (FR); Olivier TANTOT, Limoges (FR); Stephane BILA, Verneuil Sur Vienne (FR); Serge VERDEYME, Aixe Sur Vienne (FR); Laetitia ESTAGERIE, Tournefeuille (FR)

(21) Appl. No.: 13/950,670

(22) Filed: Jul. 25, 2013

(30) Foreign Application Priority Data
Jul. 27, 2012 (FR) 12 02127

(51) Int. Cl. H01P 1/20

(52) U.S. Cl. CPC H03H 7/12
USPC 333/202

(57) ABSTRACT

A band-pass filter for microwave is provided that can be frequency-tuned the filter comprising an input resonator comprising a metal input cavity and an input dielectric element, an output resonator comprising a metal output cavity and an output dielectric element, an input excitation means (S1) of elongate shape, an output excitation means of elongate shape, the input resonator and the output resonator being coupled, characterized in that the input dielectric element and the output dielectric element have a recess, the input excitation means penetrates the recess of the input dielectric element the output excitation means penetrates the recess of the output dielectric element, the input dielectric element is capable of carrying out a rotation about an input rotation axis, the rotations of the dielectric elements allowing the modification of the central frequency of the filter.

### CROSS-REFERENCE TO RELATED APPLICATION

This application claims priority to foreign French patent application No. FR 1202127, filed on Jul. 27, 2012, the disclosure of which is incorporated by reference in its entirety.

### FIELD OF THE INVENTION

The present invention relates to the field of frequency filters in the microwave domain, typically frequencies of between 1 GHz and 30 GHz. More particularly, the present invention relates to frequency-tunable band-pass filters.

### BACKGROUND

The processing of a microwave, for example received by a satellite, requires the development of specific components allowing the propagation, the amplification and the filtering of this wave.

For example, a microwave received by a satellite must be amplified before being returned to the ground. This amplification is possible only by separating all the frequencies received into channels, each corresponding to a given frequency band. The amplification is then carried out channel by channel. The separation of the channels requires the development of band-pass filters.

The development of satellites and the increased complexity of the signal processing to be carried out, for example a reconfiguration of the channels in flight, has led to the need to use frequency-tunable band-pass filters, that is to say filters for which it is possible to adjust the central filtering frequency widely named the tuning frequency of the filter.

One of the known technologies of tunable band-pass filters in the microwave domain is the use of passive semiconductor components, such as PIN diodes, continuously variable capacitors or capacitive switches. Another technology is the use of MEMS (for microelectromechanical systems) of the ohmic or capacitive type.

These technologies are complex, they consume electrical power and are not very reliable. These solutions are also limited to the level of signal power processed. In addition, frequency tunability results in a significant deterioration in the performance of the filter, such as its quality factor Q.

Furthermore, the technology of filters based on dielectric elements is known. It makes it possible to produce non-tunable band-pass filters.

FIG. 1 describes an example of a filter based on dielectric elements for non-tunable microwaves.

An input excitation means 10 inserts the wave into the cavity; this element is typically a conductive medium such as a coaxial cable (or probe).

The cavity 13 is a closed cavity made of metal, typically of aluminium or of invar.

An output excitation means 11, typically a conductive medium such as a coaxial cable (or probe) makes it possible to take the wave out of the cavity.

The dielectric element 12 is round or square in shape and placed inside the metal cavity 13. The dielectric material is typically zirconia, alumina or BMT.

A filter typically comprises at least one resonator comprising a metal cavity and a dielectric element. A resonance mode of the filter corresponds to a particular distribution of the electromagnetic field which is excited at a particular frequency.

A band-pass filter allows the propagation of a wave over a certain frequency range and attenuates this wave for the other frequencies. This therefore defines a bandwidth and a central frequency of the filter. For frequencies around its central frequency, a band-pass filter has a high transmission and a weak reflection.

In order to increase their selectivity, that is to say their capacity to attenuate the signal outside the bandwidth, these filters may be composed of a plurality of resonators that are coupled together.

The central frequency and the bandwidth of the filter depend both on the geometry of the cavities and of the dielectric elements, and on the coupling together of the resonators as well as the couplings to the input and output excitation means of the filter.

Coupling means are for example apertures or slots called irises, electrical or magnetic probes or microwave lines.

The bandwidth of the filter is characterized in different ways depending on the nature of the filter.

The parameter S is a parameter which reports the performance of the filter in terms of reflection and transmission. S11 or S22 corresponds to a measurement of the reflection and S12 or S21 to a measurement of the transmission.

A filter performs a filtering function. This function may usually be approximated via mathematical models (iterative functions such as Chebychev, Bessel, etc. functions). These functions are usually founded on polynomial ratios.

For a filter performing a filtering function of the Chebychev or generalized Chebychev type, the bandwidth of the filter is determined at equal ripple of the S11 (or S22), for example at 15 dB or 20 dB of reduction of the reflection relative to its out-band level. For a filter performing a function of the Bessel type, the band is taken at −3 dB (when S21 crosses S11).

An example of a characteristic of the parameters S11 and S12 of a filter is illustrated in FIG. 2. The curve 21 corresponds to the reflection S11 of the wave on the filter as a function of its frequency. The equal-ripple bandwidth at 20 dB of reflection is marked 26. The filter has a central frequency corresponding to the frequency of the middle of the bandwidth. The curve 22 of FIG. 2 corresponds to the transmission S12 of the filter as a function of the frequency. The filter therefore allows to pass a signal of which the frequency is situated in the bandwidth, but the signal is nevertheless attenuated by the losses of the filter.

The tuning of the filter making it possible to obtain a maximum of transmission for a given frequency band is very awkward to achieve and depends on all of the parameters of the filter. It is also dependent on the temperature.

In order to adjust the filter to obtain a precise central frequency of the filter, the resonance frequencies of the resonators of the filter may be very slightly modified with the aid of metal screws, but this method, carried out empirically, is very costly in time and provides only a very slight frequency tunability, typically of the order of a few %. In this case, the objective is not tunability but the obtaining of a precise value of the central frequency, and it is desired to obtain a reduced frequency sensitivity of each resonator with respect to the depth of the screw.

The circular or square symmetry of the resonators simplifies the design of the filter and the selection of the mode (TE for Transverse Electric or TM for Transverse Magnetic) that is propagated in the filter.

Document U.S. Pat. No. 7,705,694 describes a bandwidth-tunable filter consisting of a plurality of dielectric resonators coupled together, of non-uniform shape radially and uniform shape on an axis z perpendicular to the direction of propagation. Each resonator is capable of carrying out a rotation around the axis z between two positions, which induces a change of value of the width of the bandwidth, typically from 51 Mz to 68 Mz. This device allows tunability on the value of the width of the bandwidth of the filter, but not on its central frequency.

### SUMMARY OF THE INVENTION

The object of the present invention is to produce filters that can be tuned with respect to central frequency and that do not have the aforementioned drawbacks.

Accordingly, the subject of the invention is a band-pass filter (100) for microwave that can be frequency-tuned and has a central frequency, the microwave being propagated on an axis Z, the filter comprising:
an input resonator comprising a metal input cavity and an input dielectric element, placed inside the input cavity and capable of disrupting the resonance mode of the microwave in the input cavity,
   an output resonator comprising a metal output cavity and an output dielectric element, placed inside the output cavity and capable of disrupting the resonance mode of the microwave in the output cavity, an input excitation means of elongate shape penetrating the input cavity in order to allow the microwave to penetrate the input cavity, an output excitation means of elongate shape penetrating the output cavity in order to allow the microwave to exit the output cavity, the input resonator and the output resonator being coupled, characterized in that:
the input dielectric element and the output dielectric element have a recess,
the input excitation means of elongate shape on the axis Z penetrates the recess of the input dielectric element so that the input dielectric element disrupts the electromagnetic field close to the input excitation means,
the output excitation means of elongate shape on the axis Z penetrates the recess of the output dielectric element so that the output dielectric element disrupts the electromagnetic field close to the output excitation means,
the input dielectric element is capable of carrying out a rotation about an input rotation axis, the recess being suitable for allowing the rotation of the dielectric element while keeping the input excitation element inside the recess,
the output dielectric element is capable of carrying out a rotation about an output rotation axis, the recess being suitable for allowing the rotation of the dielectric element while keeping the output excitation element inside the recess,
each dielectric element has a flat shape having a height that is less by at least a factor of 3 than the smallest external dimension in a plane perpendicular to the direction supporting the height,
the rotations of the dielectric elements allowing the modification of the central frequency of the filter.

According to one embodiment, the input dielectric element and the output dielectric element are placed respectively substantially at the centre of the input cavity and of the output cavity.

Advantageously, the input dielectric element and output dielectric element are U-shaped.

According to one embodiment, the filter comprises a coupling means suitable for coupling the input resonator and output resonator directly.

According to one embodiment, the filter also comprises at least one intermediate resonator placed in series between the input resonator and the output resonator, comprising an intermediate metal cavity and an intermediate dielectric element placed inside the cavity and capable of disrupting the resonance mode of the microwave in the cavity, each dielectric element having a flat shape having a height less by at least a factor of 3 than the smallest dimension in a plante perpendicular to the direction supporting the height and being capable of carrying out a rotation about an intermediate rotation axis, the filter comprising coupling means suitable for coupling the intermediate resonators two by two in series

Advantageously, the coupling means are slots.

Advantageously, the dielectric elements have an identical angular position corresponding to an identical rotation, a value of the angle of rotation corresponding to a value of central frequency of the filter.

Advantageously, the rotation axes are parallel with one another.

Advantageously, the rotation axes are perpendicular to the axis Z.

Advantageously, the intermediate dielectric elements are substantially identical.

According to one embodiment, the dielectric elements are secured to respective dielectric rods capable of carrying out a rotation on the corresponding rotation axis.

According to one embodiment, the angles of rotation are variable as a function of the temperature so as to keep the central frequency values constant when there is a variation in temperature.

A further subject of the invention is a microwave circuit comprising at least one such filter.

### BRIEF DESCRIPTION OF THE DRAWINGS

Other features, objects and advantages of the present invention will become apparent on reading the following detailed description with respect to the appended drawings given as non-limiting examples and in which:

FIG. 1 illustrates an example of a dielectric resonator filter according to the prior art comprising one resonator.

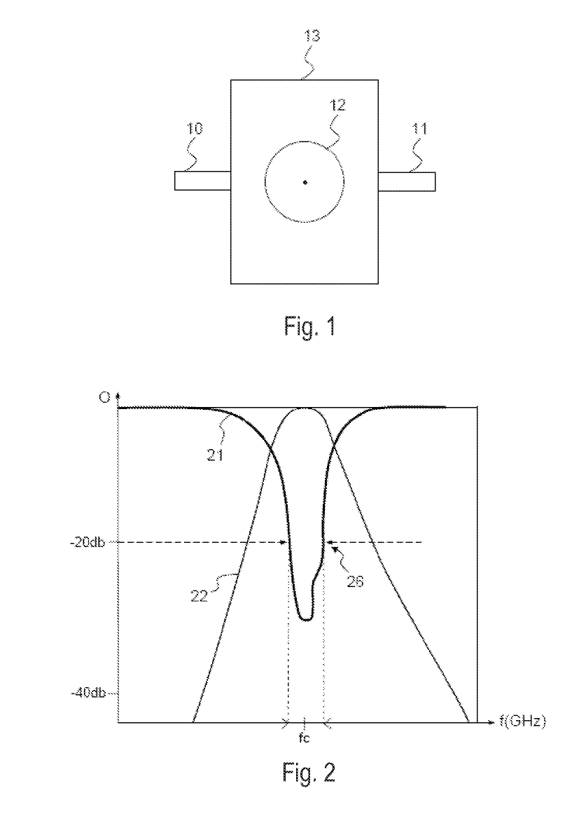

FIG. 2 describes a transmission and reflection curve of a band-pass filter.

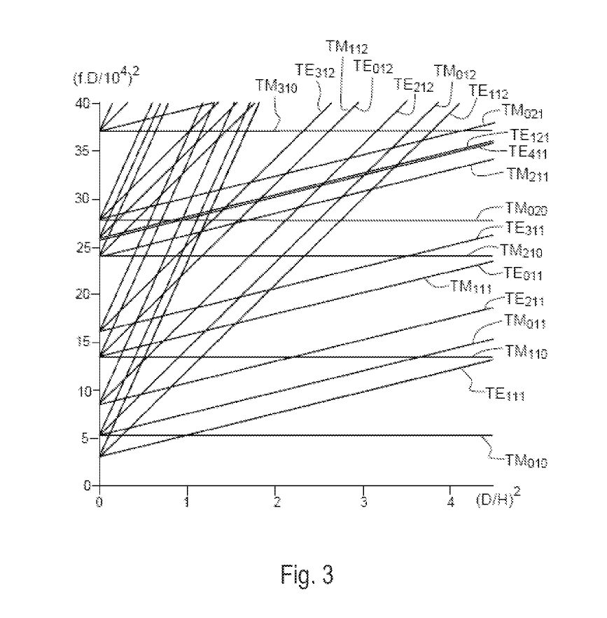

FIG. 3 illustrates the resonance modes of an empty circular cavity.

FIGS. 4A and 4B describes a filter according to one aspect of the invention.

FIG. 5 describes a filter according to one aspect of the invention seen in perspective.

FIGS. 6A, 6B, 6C, and 6D describes the position of the dielectric elements of the filter described in FIG. 5 for a determined value of rotation angle.

FIGS. 7A, 7B, 7C, 7D describes the position of the dielectric elements of the filter described in FIG. 5 for another determined value of angle of rotation.

FIGS. 8A, 8B, and 8C illustrates an exemplary embodiment of a filter according to one aspect of the invention comprising three resonators, for a determined value of angle of rotation, and the corresponding frequency curve.

FIGS. 9A, 9B, and 9C illustrates the exemplary embodiment of a filter described in FIGS. 8A-8C for another determined value of angle of rotation, and the corresponding frequency curve.
FIGS. 10A, 10B, and 10C illustrates an exemplary embodiment of a filter according to one aspect of the invention comprising six resonators for a determined value of angle of rotation, and the corresponding frequency curve.

### DETAILED DESCRIPTION

The invention consists in producing a band-pass filter that can have its central frequency tuned by rotation of dielectric elements in metal cavities, the input and output dielectric elements having a specific shape.

The filter according to the invention operates according to a disruptive cavity mode.

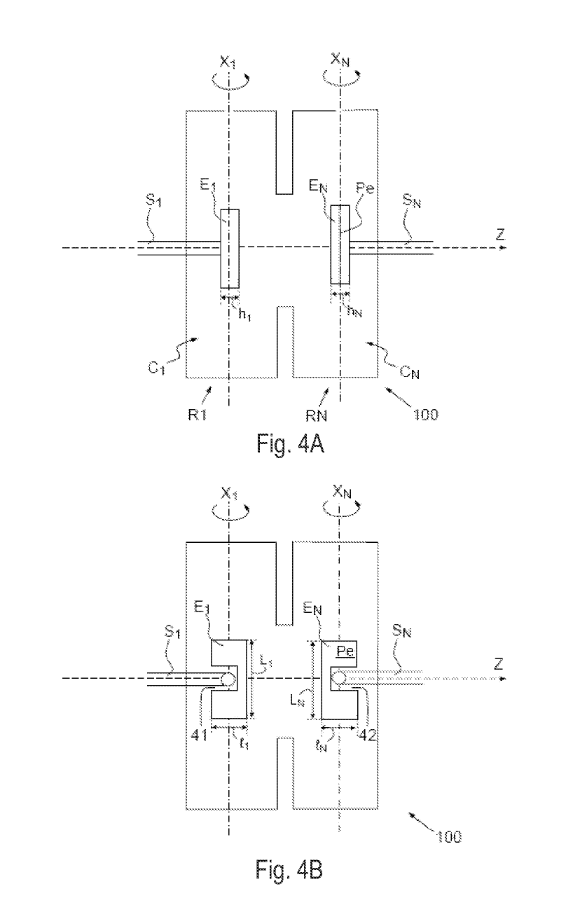

An empty metal cavity has, depending on its geometry, one or more resonance modes characterized by a frequency f of the microwave that is present in the cavity and by a particular distribution of the electromagnetic field. For example, TE (for Transverse Electric) or TM (for Transverse Magnetic) resonance modes having a certain number of energy maximums indicated by indices, can be excited in an empty metal cavity. FIG. 3 describes, as an example, the various resonance modes for an empty circular cavity as a function of the dimensions of the cavity (diameter D and height H), and of the frequency f.

A cavity containing a dielectric element (called a disrupting element) disrupting the electromagnetic field inside the cavity is also capable of resonating.

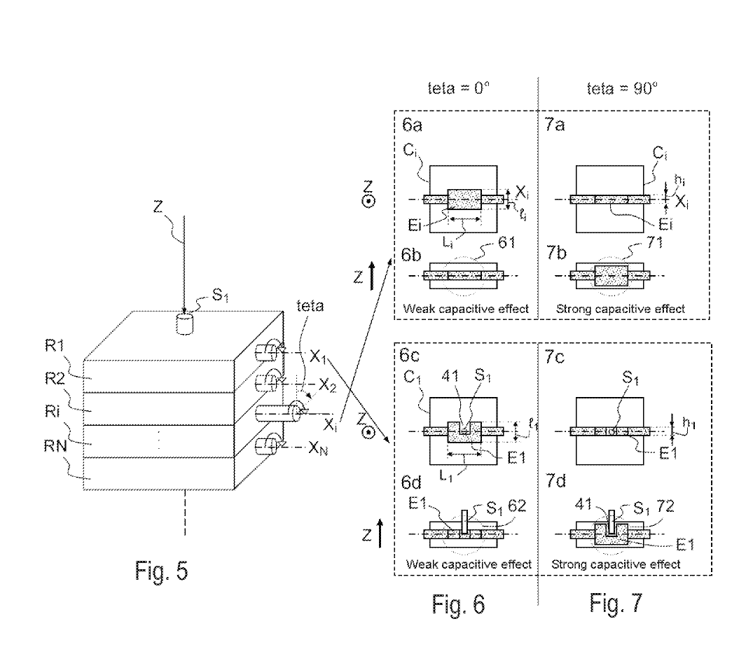

FIGS. 4A and 4B describes a band-pass filter 100 that can be frequency-tuned according to one aspect of the invention. The microwave is propagated along an axis Z.

The filter 100 comprises an input resonator R1 comprising a metal input cavity C1 and an input dielectric element E1, placed inside the cavity. The dielectric element E1 is capable of disrupting the resonance mode of the microwave in the input cavity. The intrinsic nature of the mode, corresponding to the resonance mode of the cavity without the dielectric element, is not modified, but the mode of the cavity is very disrupted by the addition of the dielectric element E1. The element E1 adds a capacitive effect which disrupts the resonance mode of the microwave in the cavity and modifies the resonance frequency of the initial resonator formed by the cavity without the dielectric element.

The filter 100 also comprises an output resonator RN comprising a metal output cavity CN and an output dielectric element EN placed inside the cavity CN. The output dielectric element EN has the same properties as those of the input dielectric element E1.

Advantageously, a TM mode is chosen on which it is easier to obtain a capacitive effect. Specifically, it is possible to approximate the frequency behaviour of a resonator by an equivalent electric circuit: a resistance-capacitance-inductance (RLC resonator) parallel association. This circuit has a resonance frequency that is a function of the product L.C. When the capacitive effect is varied, the resonance frequency varies.

For the TM mode chosen, it is easy to add a capacitive effect by increasing the permittivity at the centre of the resonator (location of the field lines E that are strongest) as described below.

In order to allow the microwave to penetrate the input cavity C1, the filter 100 comprises an input excitation means S1 of elongate shape on the axis Z penetrating the input cavity C1. This excitation means is typically a probe, such as a coaxial probe, of elongate shape, such as a cable.

In order to allow the microwave to exit the output cavity CN, the filter 100 comprises an output excitation means SN of elongate shape on the axis Z penetrating the output cavity CN. This excitation means is typically a probe, such as a coaxial probe, of elongate shape, such as a cable.

The input and output cavities are coupled together and coupled respectively to the input and output excitation means, so that the microwave inserted by the input excitation means into the filter 100 is propagated in the resonators according to a resonance mode and comes out of the filter again.

The input and output dielectric elements according to the invention have a specific shape which has a recess.

The input excitation means penetrates the recess 41 of the input dielectric element so that the input dielectric element disrupts the electromagnetic field close to the input excitation means.

The output excitation means penetrates the recess 42 of the output dielectric element so that the output dielectric element disrupts the electromagnetic field close to the output excitation means.

Because of the existence of this disruption, the central frequency of the filter is modified.

Moreover, the input dielectric element is capable of carrying out a rotation about an input rotation axis X1, the recess being suitable for allowing the rotation of the dielectric element while keeping the input excitation element inside the recess. Similarly, the output dielectric element is capable of carrying out a rotation about an output rotation axis XN, the recess being suitable for allowing the rotation of the dielectric element while keeping the output excitation element inside the recess.

Keeping the excitation element inside the recess makes it possible to maintain a strong disruption of the electromagnetic field in the vicinity of the element while ensuring a controlled coupling between excitation and resonator. This is essential to the control of the bandwidth and for the adaptation of the filter.

The distance between the excitation elements S1, SN and the respective dielectric elements E1, EN inside the recess is chosen as a function of the desired filter. A filter with large bandwidth requires a strong coupling and hence as short a distance as possible, limited by the mechanical manufacturing tolerances and the costs, typically about a hundred μm. A filter with narrow bandwidth requires a weaker coupling and hence a slightly greater distance, typically from 1 to a few mm. The rotations of the dielectric elements modify the capacitive effect, disrupting the electric field in a different manner depending on the angular position of the dielectric elements.

According to a preferred mode, the filter operates for a TM mode. For a TM mode, the magnetic field is perpendicular to the direction of propagation Z and the electric field E is colinear with Z. The preferred TM mode is of the TM₀₁₀ type. In a mode of this type, the maximum of the electric field E is concentrated at the centre of the cavity of the resonator. According to a preferred mode, the cavities of the resonators of the filter according to the invention are aligned, and the direction Z corresponds to the axis passing through the centre of the cavities. The maximum of field E is concentrated in the vicinity of Z. The capacitive effect induced by the presence of a disrupting dielectric is a function of the quantity of dielectric material (dielectric permittivity) “seen” by the field E. An increase in the quantity of dielectric “seen” by the electric field increases the capacitive effect of the resonator. The contrast obtained on the capacitive effect is maximized when this variation is located on a maximum of electric field.

For each dielectric element, a plane Pe is defined. This plane is perpendicular to the height h (smallest dimension) of the dielectric element. When each plane Pe of the dielectric elements is generally perpendicular to Z, the quantity of material traversed by the field E in the vicinity of Z is much smaller than when the planes Pe of the dielectric elements comprise the axis Z. A high contrast of capacitive effect between the two positions is obtained, which induces a greater variation of central frequency of the filter.

The rotation of a dielectric element is carried out at an angle teta relative to a given reference frame. Thus the value of the central frequency of the filter fc is a function of the angle tetaa that the element E1 makes, and of the angle tetab that the element E2 makes.

Thus, a central frequency corresponds to an angular position of the dielectric elements.

The dielectric element E1 has a flat shape having respectively a height h1 that is smaller than the external dimensions in a plane Pe perpendicular to the direction supporting the height h1. “External dimensions” means the largest dimensions (I1 and L1, in the example of FIGS. 4A and 4B) of the dielectric elements not taking account of the recess.

The dielectric element EN has a flat shape having respectively a height hN that is smaller than the external dimensions (IN and LN in the example of FIGS. 4A and 4B) in a plane Pe perpendicular to the direction supporting the height hN.

This flat shape makes it possible to obtain a great amplitude of the variation of capacitive effect between the extreme angular positions of the dielectric elements, as described above. In order to obtain an amplitude of variation of capacitive effect that is sufficient for the target applications, the height is less by at least a factor of 3 than the smallest dimension in the plane Pe perpendicular to the direction supporting the height.

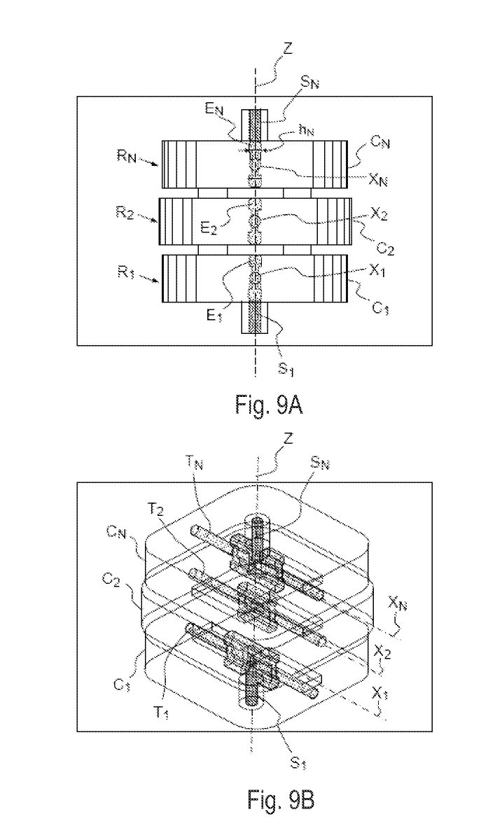

According to a preferred variant, the elements E1 and EN carry out an identical rotation, namely tetaa=tetab. FIG. 7A describes an example of a filter according to the invention when E1 and EN make an identical angle teta0, and equal to 0° by convention, corresponding to a central frequency value fc0. FIG. 7B describes the filter according to the invention when E1 and E2 make an identical angle teta90, and equal to 90° relative to the first position of E1 and E2, corresponding to a central frequency value fc90.

Thus, when the dielectric elements E1 and EN have their plane Pe substantially perpendicular to the axis Z (heights h1 hN along the axis Z corresponding to teta=0°, the height of dielectric seen by the field E (at the centre, where it is strongest) is weaker than when the dielectric elements have their plane Pe comprising substantially the axis Z (heights h1, hN perpendicular to Z corresponding to teta=90°. Thus, the capacitive effect is weaker for the position of dielectric elements according to teta=0° than for the position teta=90°.

Therefore, the filter according to the invention is a band-pass filter of which the central frequency can be chosen in a frequency range as a function of the angular orientation of the dielectric elements. Moreover, the central frequency can be chosen continuously in the span of variation.

A correction (readjustment of the central frequency) as a function of the temperature is possible.

According to one embodiment, the adjustment of the angular positions is carried out with the aid of control means, such as a motor.

According to a preferred variant, the input dielectric element E1 and the output dielectric element EN are placed respectively substantially at the centre of the input cavity and of the output cavity. This then gives a maximum concentration of the electric field in the vicinity of the input and output excitation means, which makes it possible to ensure the sufficient and controlled coupling of the excitations with the resonators 1 and N.

According to a preferred variant, the input dielectric element E1 and the output dielectric element EN are U-shaped. The shape comprises a body and two branches so as to produce a recess 41 or 42; the dielectric elements are thus easy to manufacture. There is no requirement of flatness on the shape of the dielectric elements.

According to one embodiment, the input and output excitation means are coaxial probes placed along one and the same axis Z.

According to one aspect of the invention, the filter comprises only two resonators, the input resonator R1 and the output resonator RN. The two resonators are coupled together by coupling means, such as one or more slots. According to a preferred variant, the input dielectric E1 and output dielectric EN are substantially identical in shape and material.

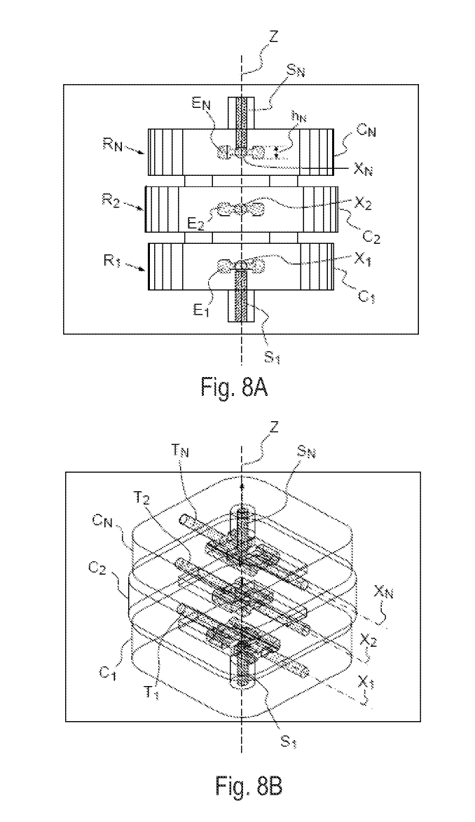

FIG. 5 describes a preferred embodiment of one aspect of the invention for which the filter 100 comprises, amongst other things, at least one intermediate resonator Ri, a resonator being numbered according to an index i varying from 2 to N−1, as a function of the number of intermediate resonators. FIG. 5A describes a view in perspective of the filter.

Each intermediate resonator Ri comprises an intermediate metal cavity Ci and an intermediate dielectric element Ei placed inside the cavity Ci and capable of disrupting the resonance mode of the microwave in the cavity, the dielectric element Ei being capable of carrying out a rotation about an intermediate rotation axis Xi.

According to a preferred variant, each intermediate dielectric element Ei also has a flat shape having a height hi less than the dimensions Li and Ii (where Ii<Li for example in FIG. 5) in a plane Pe perpendicular to the direction supporting hi. In order to obtain sufficient variation amplitude of capacitive effect for the target applications, the height hi is less by at least a factor of 3 than the smallest dimension Ii in the plane Pe perpendicular to the direction supporting the height hi.

The intermediate dielectric elements have a solid flat shape which does not necessarily have a recess because they are coupled together and not to an excitation element of elongate shape like the input and output dielectric elements.

The resonators are coupled two by two i/i+1 in series, by coupling means such as slots. These slots make it possible to couple both a portion of the electric field E and a portion of the magnetic field H. A coupling by field E has a sign opposite to a coupling by field H. In identical proportions, the two couplings cancel out. When the adjacent dielectric elements Ei/Ei+1 are rotated, for a given position and a given slot dimension, the coupling by field E (or H) varies.

According to a variant, the positions and the dimensions of the slots are determined by optimization such that the resultant bandwidth is substantially constant when the dielectric elements are rotated.

The input means S1 is a coaxial probe.

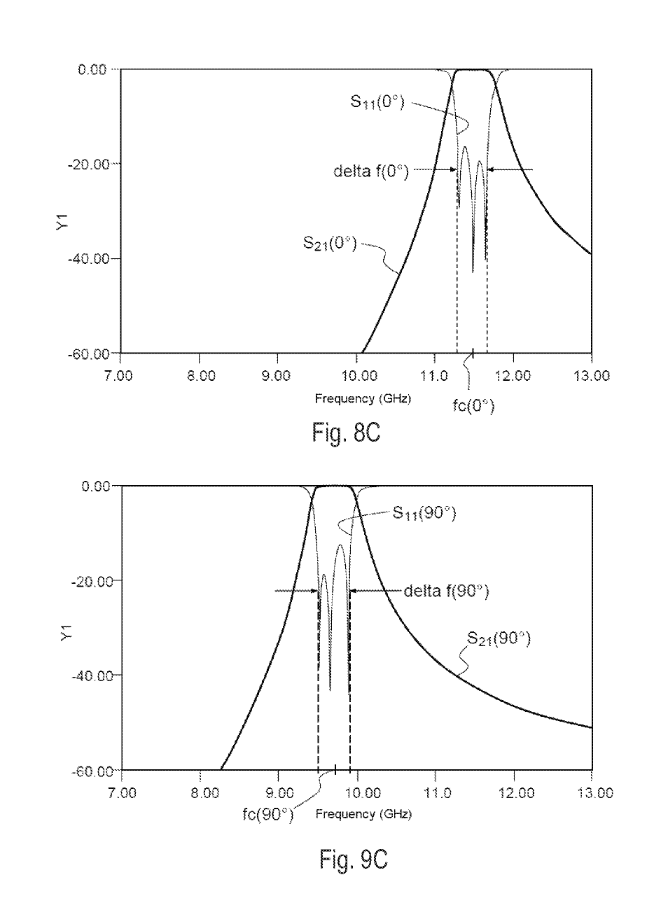

FIGS. 6A-6D and 7A-7D describe an example of two angular positions of the dielectric elements of the preferred embodiment of the invention described in FIG. 5.

According to a preferred variant shown in FIGS. 6A-6D and 7A-7D, the rotation axes from X1, X2 . . . Xi to XN are parallel with one another.

According to another variant also shown in FIGS. 6A-6D and 7A-7D, the rotation axes from X1, X2 . . . Xi to XN are perpendicular to the axis Z.

Advantageously, the rotation axes X1, X2 . . . Xi to XN are concurrent with the axis Z.

Advantageously, the intermediate elements that are symmetrical relative to the medium of the filter are identical in shape, dimension and material.

Advantageously, the intermediate elements Ei are substantially identical in shape, dimension and material.

In this geometry, the filter is easier to compute and to manufacture.

The rectangular shape of the dielectric elements shown is purely schematic and does not correspond to a preferred shape.

FIG. 6 describes the structure of the dielectric elements for a value of teta=0°. FIG. 6A corresponds to an intermediate element Ei in a cavity Ci in a view from above, FIG. 6B in a view in profile. The zone in the dotted line 61 illustrates a configuration in which the capacitive effect is weak. FIG. 6C corresponds to the input dielectric element E1 in the cavity C1 in a view from above, FIG. 6D in a view in profile. The zone in dotted line 62 illustrates a configuration in which the capacitive effect is weak. In FIG. 6C, the recess 41 and the U shape of E1 are visible. A central frequency of the filter fc0 is associated with this position teta=0°, corresponding to the dielectric elements positioned perpendicularly to the axis Z.

FIG. 7 describes the structure of the dielectric elements for a value of teta=90°. FIG. 7A corresponds to an intermediate element Ei in a cavity Ci in a view from above, FIG. 7B in a view in profile. The zone in the dotted line 71 illustrates a configuration in which the capacitive effect is strong. FIG. 7C corresponds to the input dielectric element E1 in the cavity C1 in a view from above, FIG. 7D in a view in profile. The zone in the dotted line 72 illustrates a configuration in which the capacitive effect is strong. In FIG. 7C the recess 41 and the U shape of E1 can be seen. A central frequency of the filter fc90 is associated with this position teta=90°.

Intermediate central frequencies are obtained for values of teta of between 0° and 90°.

Preferably, all the dielectric elements E1, Ei, EN have an identical angular position corresponding to an identical rotation, a value of the angle of rotation teta corresponding to a value of central frequency:

fc=f(teta)

A progressive and synchronous rotation of the dielectric elements E1, Ei, EN makes it possible to continuously vary the central frequency fc of the filter.

To obtain a change of central frequency when the disrupting elements E1, Ei, EN are rotated, none of these elements has symmetry of revolution about its respective rotation axis.

Thus the rotation made by each dielectric element E1, Ei, EN varies the quantity of material traversed by the electric field E at the centre of the cavities of the resonators, which has the effect of varying the capacitive effect of the resonator.

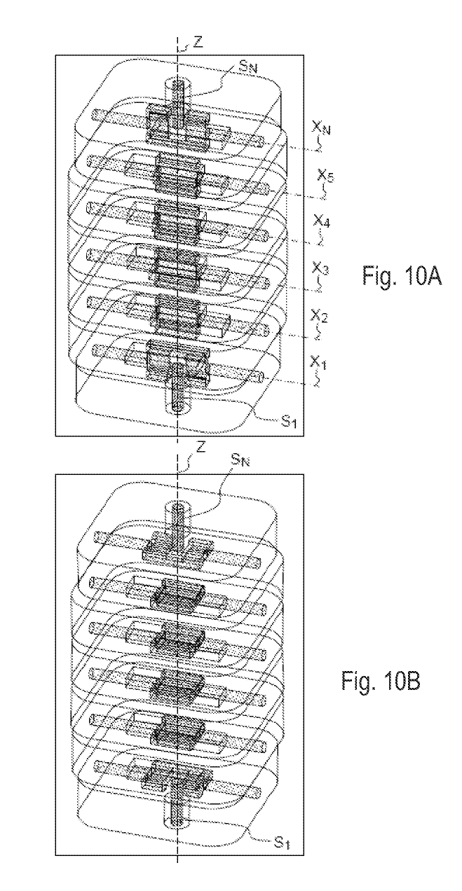

FIGS. 8A-8C and FIGS. 9A-9C illustrate an exemplary embodiment of a filter according to the invention and the filter characteristics obtained.

The filter comprises 3 resonators R1, R2, RN comprising cavities C1, C2, CN of substantially square shape.

The dimension of the cavities C1 and CN is 16 mm, the dimension of C2 is 17 mm. The 3 cavities have a height of 4.5 mm.

The dielectric elements E1, E2, EN are made of zirconia. The input dielectric element E1 and output dielectric element EN have a dimension of 3.8 mm×6.1 mm×1.2 mm. The height h of 1.2 mm is less than the other dimensions by approximately a factor of 3 with the smallest of the two other dimensions.

The dimensions of the intermediate dielectric element E2 are 4 mm×4.1 mm×1.2 mm (height h of 1.2 mm).

The resonators R2 and RN are connected by two slots of dimension 7 mm×2.5 mm, 5.5 mm apart. Screws not shown (6 per cavity) allow a fine adjustment of the resonance of the TM mode and of the couplings.

FIG. 8 corresponds to an angle value teta=0°, the elements are generally perpendicular to the axis Z (height h along Z, plane Pe perpendicular to Z), corresponding to a weak capacitive effect. FIG. 8A represents a view in profile of the filter and FIG. 8B a view in perspective.

FIG. 9 corresponds to an angle value teta=90° of angle of rotation of the dielectric elements, the elements are generally parallel to the axis Z (height h perpendicular to Z, plane Pe comprising the axis Z), corresponding to a strong capacitive effect. FIG. 9A represents a view in profile of the filter and FIG. 9B a view in perspective.

In this example, the flat shapes of the dielectric elements are optimized to maximize the difference of capacitive effect and hence of the frequency shift.

According to a preferred variant shown in FIGS. 8A-8C and FIGS. 9A-9C, the dielectric elements E1, E2, EN are secured to retention means, preferably respective rods T1, T2, TN also made of dielectric material capable of carrying out a rotation.

Advantageously, a rod and the dielectric element that is secured to it form a single block of one and the same dielectric material which is manufactured in one piece. In this case, and more generally when the rod is made of dielectric material, it contributes to the disrupting effect of the dielectric element. Preferably the rods Ti pass right through the associated disrupting element Ei and the cavity Ci, which ensures a better mechanical retention of the dielectric element in the cavity than with a single retention point.

These rods may carry out a rotation on the corresponding rotation axis X1, X2, XN with the aid of a pivot connection with the walls of the cavity C1, C2, CN in which they are found. There are therefore fewer technological steps for the manufacture of the filter.

FIG. 8C illustrates the frequency behaviour of the band-pass filter obtained for teta=0°. The curve S21(0°) corresponds to the transmission of the filter and the curve S11(0°) to the reflection. The bandwidth at −20 dB is deltaf(0°) and the central frequency fc(0°) is equal to 11.5 GHz.

FIG. 9C illustrates the frequency behaviour of the band-pass filter obtained for teta=90°. The curve S21(90°) corresponds to the transmission of the wire and the curve S11(90°) to the reflection. The bandwidth at −20 dB is deltaf(90°) and the central frequency fc(90°) is equal to 9.65 GHz.

Thus, by rotation through an angle of 90°, the central frequency is modified from 9.65 GHz to 11.5 GHz.

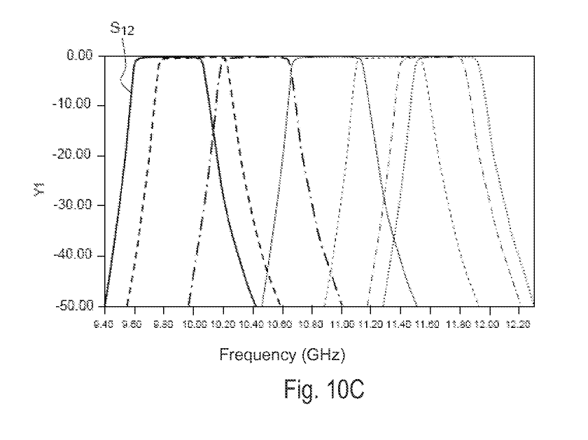

FIG. 10 illustrates another embodiment of a filter according to the invention in the same spirit as the filter described in FIGS. 8A-8C and FIGS. 9A-9C. FIG. 10A describes a view in perspective of the filter for dielectric elements that are generally parallel to the axis Z and FIG. 10B describes a view in perspective of the filter for the dielectric elements that are generally perpendicular to the axis Z. The filter comprises 6 resonators. FIG. 10C describes the transmission of the filter S12 for various angular positions of the dielectric elements between 0° and 90°. The central frequency varies as a function of the angle of inclination of the dielectric elements, between 9.65 GHz and 11.5 GHz.

The adaptation is of the order of 15 dB and the losses of the filter between 0.3 and 0.5 dB irrespective of the value of the angle of rotation.

For the filters according to the invention, the input and the output play a symmetrical role.

The variations in temperature (typically a few tens of degrees) in the filter induce fluctuations in the dimensions of the cavities and of the dielectric elements, which generates variations of central frequency for one and the same filter geometry.

According to one embodiment of the filter according to the invention, angles of rotation of the dielectric elements have values that can be varied as a function of the temperature so as to correct the effects of the temperature on the central frequencies and hence keep the values of these central frequencies constant during a variation in temperature.

Preferably, each value of central frequency corresponds to an angle of rotation that is identical for all the dielectric elements of the filter according to the invention and the value of this angle is temperature-controlled so as to keep the central frequency at a determined value independent of the temperature.

According to another aspect, the invention also relates to a microwave circuit comprising at least one filter according to the invention.

1. A band-pass filter for microwave that can be frequency-tuned and has a central frequency (fc), the microwave being propagated on an axis Z, the filter comprising:
an input resonator comprising a metal input cavity and an input dielectric element, placed inside the input cavity and capable of disrupting the resonance mode of the microwave in the input cavity,
an output resonator comprising a metal output cavity and an output dielectric element, placed inside the output cavity and capable of disrupting the resonance mode of the microwave in the output cavity,
an input excitation means of elongate shape on the axis Z penetrating the input cavity in order to allow the microwave to penetrate the input cavity,
an output excitation means of elongate shape on the axis Z penetrating the output cavity in order to allow the microwave to exit the output cavity,
the input resonator and the output resonator being coupled,
wherein the input dielectric element and the output dielectric element have a recess,
wherein the input excitation means penetrates the recess of the input dielectric element so that the input dielectric element disrupts the electromagnetic field close to the input excitation means,
wherein the output excitation means penetrates the recess of the output dielectric element so that the output dielectric element disrupts the electromagnetic field close to the output excitation means,
wherein the input dielectric element is capable of carrying out a rotation about an input rotation axis, the recess being suitable for allowing the rotation of the dielectric element while keeping the input excitation element inside the recess,
wherein the output dielectric element is capable of carrying out a rotation about an output rotation axis, the recess being suitable for allowing the rotation of the dielectric element while keeping the output excitation element inside the recess,
wherein each dielectric element has a flat shape having a height that is less by at least a factor of 3 than the smallest external dimension in a plane perpendicular to the direction supporting the height, and
wherein the rotations of the dielectric elements allowing the modification of the central frequency of the filter.

2. The filter according to claim 1, in which the input dielectric element and the output dielectric element are placed respectively substantially at the centre of the input cavity and of the output cavity.

3. The filter according to claim 1, in which the input dielectric element and output dielectric element are U-shaped.

4. The filter according to claim 1, comprising coupling means suitable for coupling the input resonator and output resonator directly.

5. The filter according to claim 1, also comprising at least one intermediate resonator placed in series between the input resonator and the output resonator, comprising at least an intermediate metal cavity and an intermediate dielectric element placed inside the cavity and capable of disrupting the resonance mode of the microwave in the cavity, each dielectric element having a flat shape having a height less by at least a factor of 3 than the smallest dimension in a plane perpendicular to the direction supporting the height and being capable of carrying out a rotation about an intermediate rotation axis, the said filter comprising coupling means suitable for coupling the intermediate resonators two by two in series.

6. The filter according to claim 1, in which the coupling means are slots.

7. The filter according to claim 1, in which the dielectric elements have an identical angular position corresponding to an identical rotation, a value of the angle of rotation corresponding to a value of central frequency of the filter.

8. The filter according to claim 1, in which the rotation axes are parallel with one another.

9. The filter according to claim 1, in which the rotation axes are perpendicular to the axis Z.

10. The filter according to claim 5, in which the intermediate dielectric elements are substantially identical.

11. The filter according to claim 1, in which the dielectric elements are secured to respective dielectric rods capable of carrying out a rotation on the corresponding rotation axis.

12. The filter according to claim 1, in which the angles of rotation are variable as a function of the temperature so as to keep the central frequency values constant when there is a variation in temperature.

13. A microwave circuit comprising at least one filter according to claim 1.
